(19) United States
(12) Patent Application Publication
(10) Pub. No.: US 2015/0062849 A1
(43) Pub. Date: Mar. 5, 2015

(54) PRINTED WIRING BOARD

(71) Applicant: IBIDEN CO., LTD., Ogaki-shi (JP)

(72) Inventors: Takema ADACHI, Ogaki-shi (JP); Satoshi Kondo, Ogaki-shi (JP)

(73) Assignee: IBIDEN CO., LTD., Ogaki-shi (JP)

(21) Appl. No.: 14/470,976

(22) Filed: Aug. 28, 2014

(30) Foreign Application Priority Data
Aug. 28, 2013 (JP) 2013-176176

(51) Int. Cl. H05K 1/02; H05K 1/11; H05K 1/18

(52) U.S. Cl. CPC H05K 1/0296; H05K 1/185; H05K 1/11; H05K 2201/10204; H05K 2201/09227
USPC 361/761; 174/261

(57) ABSTRACT

A wiring board includes a unit section including product portions, and a frame section formed along the periphery of the unit section. The frame section has a dummy pattern which includes conductive portions and connection lines such that the connection lines are formed in spaces between the conductive portions and linking the conductive portions.

### CROSS-REFERENCE TO RELATED APPLICATIONS

The present application is based upon and claims the benefit of priority to Japanese Patent Application No. 2013-176176, filed Aug. 28, 2013, the entire contents of which are incorporated herein by reference.

### BACKGROUND OF THE INVENTION

1. Field of the Invention

The present invention relates to a printed wiring board having a unit section containing multiple products and a frame section formed along the periphery of the unit section.

2. Description of Background Art

JP2011-18716A describes a printed wiring board having dummy wiring lines. According to JP2011-18716A, dummy wiring lines are formed only on one surface of a printed wiring board that has solder-resist layers on both of its surfaces. In addition, dummy wiring lines are formed intermittently. The entire contents of this publication are incorporated herein by reference.

### SUMMARY OF THE INVENTION

According to one aspect of the present invention, a wiring board includes a unit section including product portions, and a frame section formed along the periphery of the unit section. The frame section has a dummy pattern which includes conductive portions and connection lines such that the connection lines are formed in spaces between the conductive portions and linking the conductive portions.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a plan view of a printed wiring board according to a first embodiment of the present invention;

FIG. 2(A)-2(B) are a cross-sectional view of a package substrate of the first embodiment and a view schematically showing a first surface of the core substrate;

FIG. 3(A)-3(E) are views showing steps of a method for manufacturing a printed wiring board of the first embodiment;

FIG. 4(A)-4(E) are views showing steps of the method for manufacturing a printed wiring board of the first embodiment;

FIG. 5(A)-5(E) are views showing steps of the method for manufacturing a printed wiring board of the first embodiment;

FIG. 6(A)-6(D) are views showing the size of a dummy pattern and the width of a space;

FIG. 7(A)-7(D) are plan views of a dummy pattern according to the first embodiment;

FIG. 8(A)-8(E) are views schematically showing dummy patterns according to modified examples;

FIG. 9(A)-9(C) are views schematically showing dummy patterns according to modified examples;

FIG. 10(A)-10(C) are views schematically showing dummy patterns according to modified examples;

FIG. 11(A)-11(C) are views schematically showing dummy patterns according to modified examples; and

FIG. 12(A)-12(C) are views schematically showing dummy patterns according to modified examples.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

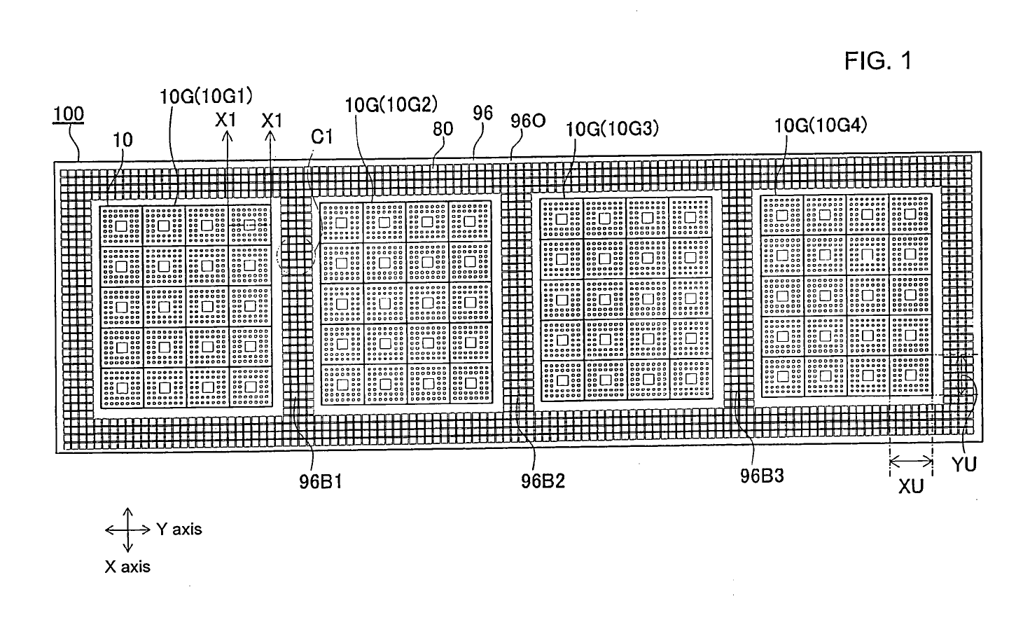

FIG. 1 shows a plan view of printed wiring board 100 according to a first embodiment of the present invention. Printed wiring board 100 is made up of unit section (10G) which includes multiple products 10, and of frame section 96 formed along the periphery of unit section (10G). Substantially rectangular unit section (10G) is surrounded by frame section 96. The outline of printed wiring board 100 is substantially rectangular. In FIG. 1, printed wiring board 100 has four unit sections (10G1, 10G2, 10G3, 10G4). In FIG. 1, products 10 are formed in a 4×5 matrix in each unit section. Frame section 96 includes outer frame section (96O) that surrounds all unit sections (10G1, 10G2, 10G3, 10G4) and inner frame sections (96B1, 96B2, 96B3) each positioned between unit sections. As shown in FIG. 1, each unit section is surrounded by a frame.

As shown in FIG. 1, dummy pattern 80 made up of conductive portions and connection lines is formed in the frame section. Axis (X) and axis (Y) perpendicular to axis (X) are indicated in FIG. 1. The printed wiring board shown in FIG. 1 is rectangular, and its long side is parallel to axis (Y) and its short side is parallel to axis (X). In the first embodiment, conductive portions and products are formed substantially parallel to the periphery of the printed wiring board. The conductive portions are formed parallel to the products in each unit section of the printed wiring board in the first embodiment. Conductive portions are formed parallel to axis (X). Conductive portions are formed parallel to axis (Y). Conductive portions are arrayed parallel to the products.

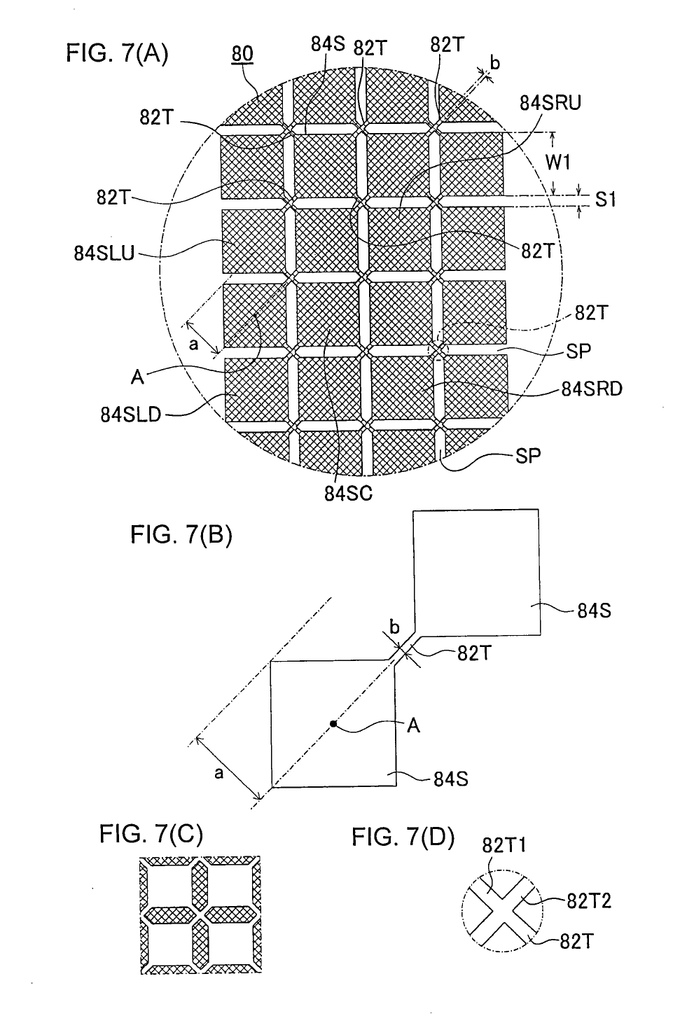

FIG. 7 shows an enlarged view of dummy pattern 80 formed in circle (C1) in FIG. 1. Lines are drawn in portions corresponding to conductive portions and connection lines. Dummy pattern 80 of the printed wiring board in the first embodiment has conductive portions (84S) arrayed in a matrix. A conductive portion belongs either in a row or in a column. Rows are parallel to axis (X) and columns are parallel to axis (Y). An example of the shape of a conductive portion is a polygon. The shape of a conductive portion is preferred to be a regular polygon. The conductive portions shown in FIG. 7 are shaped to be a square. One conductive portion (84S) is linked to multiple conductive portions by connection lines (82T). Also, space (SP) is present between conductive portions. A connection line is formed inside such a space. In the first embodiment, a connection line exists in a space. Thus, the rigidity of the printed wiring board is enhanced by connection lines between conductive portions. Stress is mitigated by the space between conductive portions. Conductive portions are not independent of each other, and conductive portions are restricted by connection lines. It is difficult for conductive portions to move freely because of connection lines. Conductive portions, connection lines and spaces suppress deformation in the frame section. As a result, the printed wiring board is not likely to become easily deformed. Warping in the printed wiring board is reduced. Also, complex deformation such as undulation is unlikely to occur. The directions of warping in the printed wiring board tend to be uniform in a specific direction. It is easier to mount electronic components on the printed wiring board.

The area of a conductive portion is greater than the area of a connection line. When the shape of a conductive portion is a polygon, distance (a) from gravity center (A) of the polygon to an apex is preferred to be at least 1.5 times, but no more than seven times, the width (b) of a connection line. Distance (a) and width (b) are indicated in FIGS. 7(A) and (B). When semiconductor elements are mounted on the printed wiring board of the first embodiment, the proportion of conductor volume in a space is set appropriately. Therefore, even when semiconductor elements are mounted on the printed wiring board, warping of the printed wiring board is reduced.

In the first embodiment, a conductive portion, except for those at the end of a row or a column, is linked to four conductive portions by connection lines (82T). In the first embodiment, a conductive portion is linked to conductive portions positioned diagonally above or below, or a conductive portion is linked to conductive portions positioned diagonally above and below. Among the conductive portions shown in FIG. 7, conductive portion (84SC) is linked by four connection lines to conductive portion (84SRU) positioned diagonally above to the right, conductive portion (84SRD) positioned diagonally below to the right, conductive portion (84SLU) positioned diagonally above to the left, and conductive portion (84SLD) positioned diagonally below to the left. A connection line extends from an apex (corner) or a side of a conductive portion. Then, an apex of a conductive portion is linked to an apex of another conductive portion, or an apex of a conductive portion is linked to a side of another conductive portion. Alternatively, a side of a conductive portion may be linked to a side of another conductive portion. A conductive portion is preferred to be linked to another conductive portion by the shortest possible connection line. In FIG. 7(A), an apex of a conductive portion is linked to an apex of another conductive portion by a connection line.

FIG. 7(D) shows an enlarged view of connection lines. In the first embodiment, conductive portions positioned diagonally to each other are linked by connection lines. Thus, as shown in FIG. 7(D), one connection line (82T1) intersects another connection line (82T2). Accordingly, the force of binding conductive portions by connection lines increases. Also, the strength of connection lines improves. Thus, the rigidity of the frame section is enhanced. The width of a connection line can be set thinner. For example, the width of a connection line is set at 0.03˜0.07 mm. The effect of mitigating stress by spaces increases. Warping in the printed wiring board decreases. Distortion is less likely to occur. Each conductive portion is unlikely to move at random when heat is applied during a mounting process. It becomes easier to mount electronic components such as IC chips on the printed wiring board. Since warping or undulation during the mounting process is small, connection reliability is enhanced between semiconductor elements and the printed wiring board.

When the shape of a conductive portion is square, an apex of conductive portion (84S) is linked to an apex of another conductive portion (84S). Connection line (82T) is set to extend from an apex of conductive portion (84S) diagonally at 45 degrees to a row of the matrix. Conductive portion (84SC) is linked to conductive portion (84SRU) positioned diagonally above to the right in the drawing. The connection line extending from the upper right apex of conductive portion (84SC) reaches the lower left apex of conductive portion (84SRU). Further, conductive portion (84SC) is linked to conductive portion (84SRD) positioned diagonally below to the right in the drawing. The connection line extending from the lower right apex of conductive portion (84SC) reaches the upper left apex of conductive portion (84SRD). Yet furthermore, conductive portion (84SC) is linked to conductive portion (84SLU) positioned diagonally above to the left in the drawing. The connection line extending from the upper left apex of conductive portion (84SC) reaches the lower right apex of conductive portion (84SLU). Yet furthermore, conductive portion (84SC) is linked to conductive portion (84SLD) positioned diagonally below to the left in the drawing. The connection line extending from the lower left apex of conductive portion (84SC) reaches the upper right apex of conductive portion (84SLD).

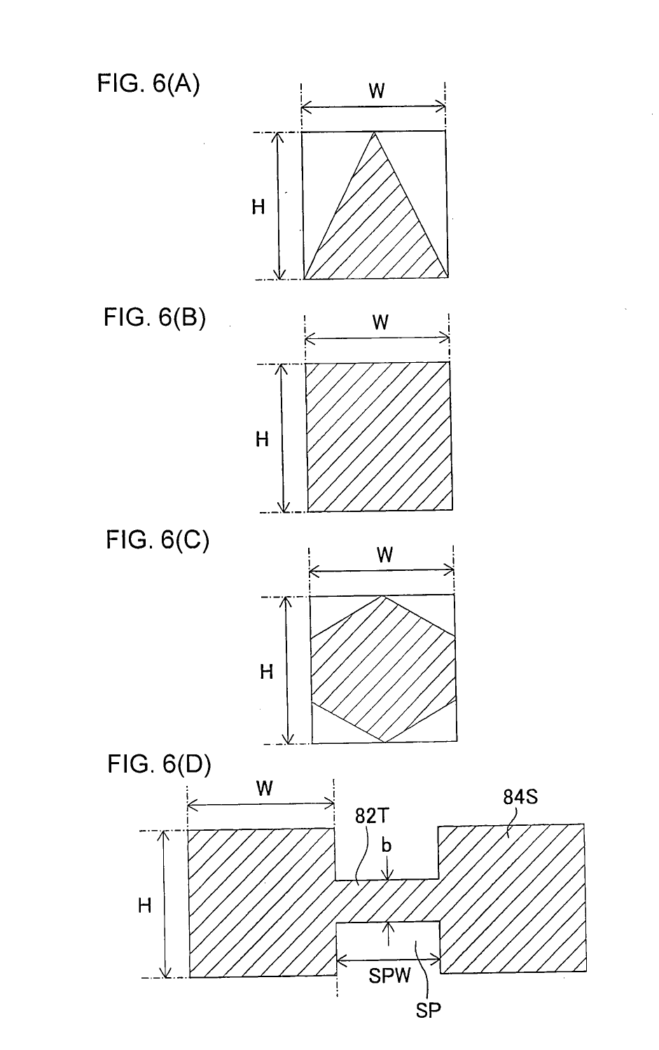

A polygonal conductive portion has height (H) and width (W). Since conductive portions are arrayed in a matrix, a conductive portion is sandwiched by two straight lines parallel to a row and two straight lines parallel to a column. Such a straight line is in contact with an apex or a side of the conductive portion. The distance between two straight lines parallel to a row is height (H). The distance between two straight lines parallel to a column is width (W). When the shape of a conductive portion is a triangle, an example of height (H) and width (W) is shown in FIG. 6(A). When the shape of a conductive portion is a rectangle, an example of height (H) and width (W) is shown in FIG. 6(B). When the shape of a conductive portion is a hexagon, its height (H) and width (W) are indicated in FIG. 6(C). FIG. 6(D) shows connection line (82T) having width (b) and space (SP) having width (SPW). Width (SPW) is the distance between adjacent conductive portions. Height (H) is 0.2 mm to 0.8 mm, width (W) is 0.2 mm to 0.8 mm. Also, width (b) of a connection line is 0.03 mm to 0.2 mm. Width (SPW) of a space is 0.05 mm to 0.2 mm. When the dimensions of a conductive portion, the width of a connection line and the width of a space are set respectively within the above ranges, the ratio of the area of conductive portions and the area of spaces inside the frame section is appropriate. Also, if connection lines intersect each other, even when the thickness of the printed wiring board is 0.35 mm or less, warping is small in the printed wiring board. Connection reliability improves between the printed wiring board and IC chips. The width of a connection line is preferred to be 0.03 mm to 0.08 mm. Since the volume of space within the frame section increases, stress is mitigated by the space. The thickness of the printed wiring board is 0.1 mm or greater. Warping is reduced.

When a conductor is formed on the entire surface of the frame section, the rigidity of frame section 96 tends to increase more than the rigidity of the unit section. In addition, since no space exists in the frame section, it is difficult to mitigate stress in the frame section of the printed wiring board. Thus, warping tends to be greater. However, in the first embodiment, since the frame section is made up of conductive portions, connection lines and spaces, the rigidity of the unit section is similar to that of the frame section. Accordingly, warping is less likely to occur. When a space is formed between conductive portions, the rigidity of the frame section decreases. However, since there are connection lines linking conductive portions to each other in the first embodiment, warping is less likely to occur along spaces. Connection lines intersect in the first embodiment. Intersecting connection lines reinforce the frame section. Moreover, spaces are present between conductive portions. Thus, deformation or bending of the printed wiring board is prevented.

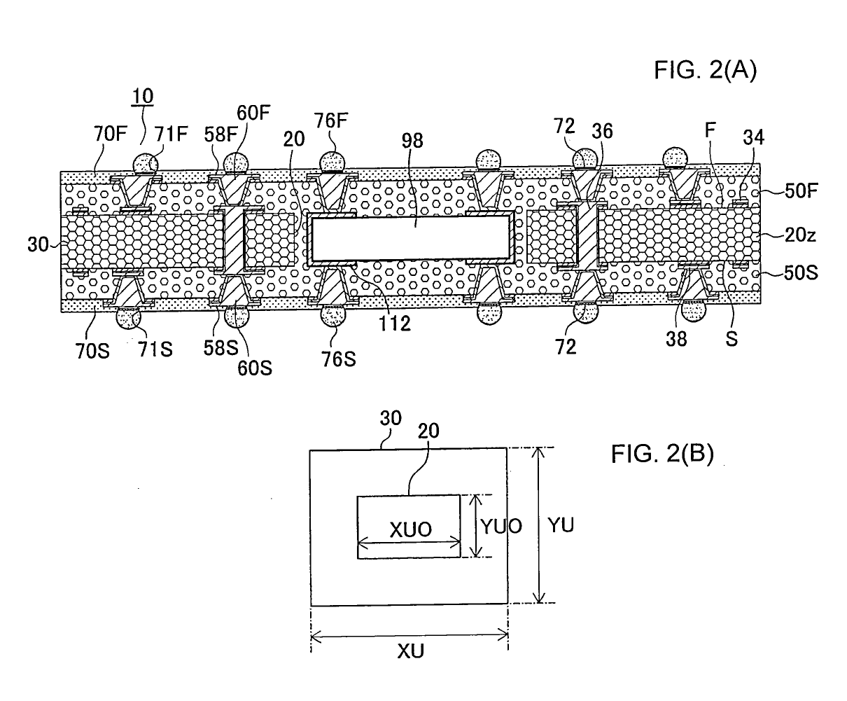

FIG. 2(A) is a cross-sectional view taken at (X1-X1) of FIG. 1. FIG. 2(A) shows a cross-sectional view of product (package substrate) 10. Package substrate 10 has core substrate 30 having first surface (F) and second surface (S) opposite first surface (F). Core substrate 30 has insulative base (20z) having first surface (F) and second surface (S), first conductive layer 34 formed on first surface (F) of insulative base (20z), second conductive layer 38 formed on second surface (S), through-hole conductor 36 penetrating through insulative base (20z) and connecting the first conductive layer and the second conductive layer, and opening (penetrating hole) 20 to accommodate an electronic component. Electronic component 98 is accommodated in penetrating hole 20. The electronic component is an active component such as a semiconductor element or a passive component such as a capacitor. The first surface of the core substrate corresponds to the first surface of the insulative base, and the second surface of the core substrate corresponds to the second surface of the insulative base. The package substrate of the embodiment has opening 20 and electronic component 98. Accordingly, the printed wiring board tends to warp. Especially, if the planar area of opening 20 (XUO×YUO) occupies 40˜80% of the planar area of a package substrate (XU×YU), warping increases. However, since the printed wiring board of the embodiment has a frame section, warping of the printed wiring board is reduced. (XU, XUO, YU, YUO) are indicated in FIG. 1 and FIG. 2(B). FIG. 2(B) is a view showing the first surface of the core substrate, but conductive layers are not shown there. FIG. 2(B) shows the outline of a package substrate.

An upper buildup layer is formed on first surface (F) of core substrate 30 and on electronic component 98. The upper buildup layer is formed with uppermost insulation layer (50F) formed on first surface (F) of core substrate 30 and on electronic component 98, uppermost conductive layer (58F) formed on uppermost insulation layer (50F), and uppermost via conductor (60F) penetrating through uppermost insulation layer (50F) and connecting the first conductive layer and uppermost conductive layer (58F). Uppermost conductive layer (58F) includes the conductive portions and connection lines formed in the frame section.

A lower buildup layer is formed on second surface (S) of core substrate 30 and on electronic component 98. The lower buildup layer is formed with lowermost insulation layer (50S) formed on second surface (S) of core substrate 30 and on the electronic component, lowermost conductive layer (58S) formed on lowermost insulation layer (50S), and lowermost via conductor (60S) penetrating through lowermost insulation layer (50S) and connecting the second conductive layer and lowermost conductive layer (58S). Lowermost conductive layer (58S) includes the conductive portions and connection lines formed in the frame section.

Upper solder-resist layer (70F) having opening (71F) is formed on the upper buildup layer. Lower solder-resist layer (70S) having opening (71S) is formed on the lower buildup layer. Portions of conductive layers (58F, 58S) exposed through openings (71F, 71S) of solder resist layers (70F, 70S) work as pads. Metal film 72 made of Ni/Au, Ni/Pd/Au or the like is formed on the pads, and solder bumps (76F, 76S) are formed on the metal film. An IC chip is mounted on each package substrate through solder bumps (76F). When a semiconductor element such as an IC chip is mounted on a package substrate, an applied example of the package substrate is completed. Each applied example is cut out individually from the printed wiring board. Then, applied example 10 is mounted on a motherboard through solder bumps (76S).

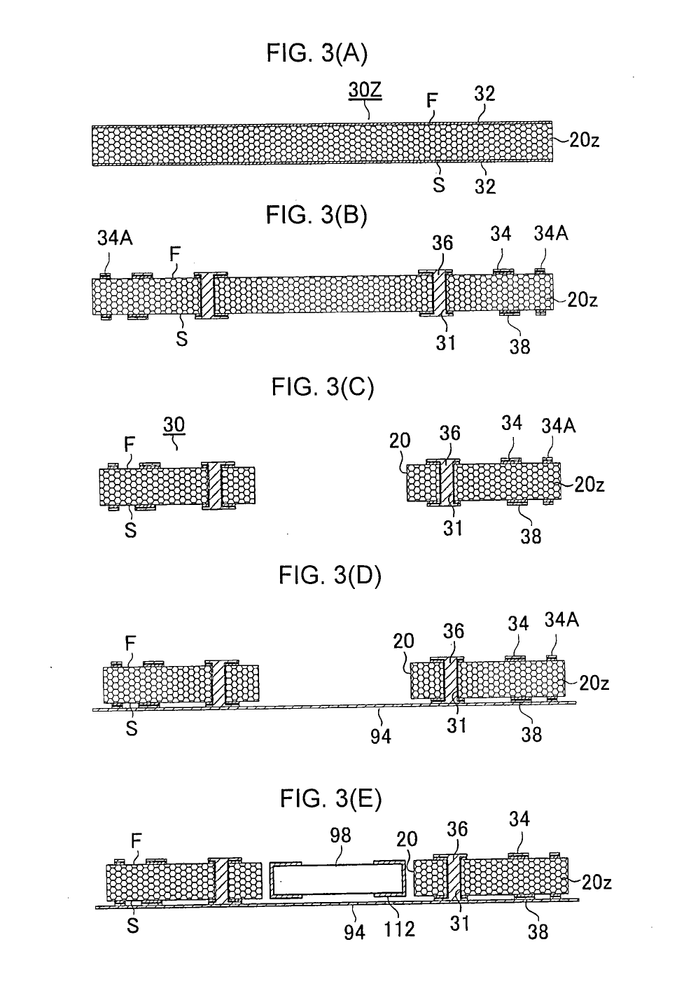

A method for manufacturing printed wiring board 10 of the first embodiment is shown in FIG. 3˜FIG. 6.

(1) Double-sided copper-clad laminate (30Z) is prepared as a starting material (FIG. 3(A)). Double-sided copper-clad laminate (30Z) is formed with insulative base (20z) and copper foil 32 laminated on both surfaces of insulative base (20z).

(2) Penetrating hole 31 for a through-hole conductor is formed in the starting material. Then, through-hole conductor 36 is formed in the penetrating hole. After that, first conductive layer 34 is formed on a first surface of the insulative base, and second conductive layer 38 is formed on a second surface of the insulative base (FIG. 3(B)). The first conductive layer includes alignment mark (34A).

(3) Next, based on alignment mark (34A), opening 20 is formed to penetrate through the insulative base (FIG. 3(C)). Core substrate 30 is completed.

(4) Tape 94 is laminated on second surface (S) of core substrate 30. Opening 20 is covered by the tape (FIG. 3(D)). An example of tape 94 is PET film.

(5) Based on alignment mark (34A), electronic component 98 is mounted on tape 94 exposed through opening 20 (FIG. 3(E)).

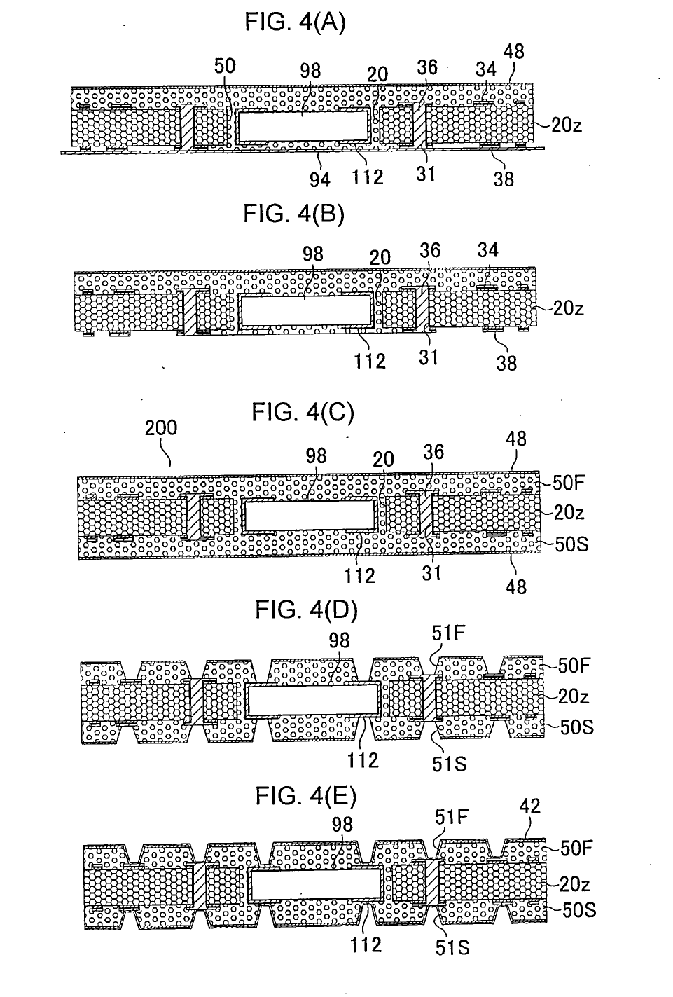

(6) B-stage prepreg and copper foil 48 are laminated on first surface (F) of core substrate 30. When hot pressing is applied, resin seeps into the opening from the prepreg and opening 20 is filled with resin (resin filler) 50. At the same time, the prepreg is laminated on the core substrate (FIG. 4(A)). The space between the electronic component and the inner walls of opening 20 is filled with the resin filler. The electronic component is fixed to the core substrate. Instead of prepreg, resin film for forming interlayer resin insulation layers may be laminated. Prepreg contains reinforcing material such as glass cloth, but resin film for interlayer resin insulation layers does not contain reinforcing material. Both resin materials are preferred to contain inorganic particles. Filler resin contains inorganic particles of silica or the like.

(7) After the tape is removed, residue on electrodes 112 of electronic component 98 is removed by plasma treatment (FIG. 4(B)).

(8) B-stage prepreg and copper foil 48 are laminated on second surface (S) of core substrate 30. The prepreg on the first and second surfaces of the core substrate is cured. Uppermost insulation layer (interlayer resin insulation layer) (50F) is formed on the first surface of the core substrate. Lowermost insulation layer (interlayer resin insulation layer) (50S) is formed on the second surface of the core substrate (FIG. 4(C)). Intermediate substrate 200 is completed. Intermediate substrate 200 may be formed by a method described in US 2012/0186866 A1, for example. The contents of US 2012/0186866 A1 are incorporated in this application. In the first embodiment, a capacitor may be built into the core substrate as shown in FIG. 1 of US 2012/0186866 A1.

(9) In the uppermost insulation layer, via-conductor opening (51F) is formed to reach the first conductive layer, a through-hole conductor or an electrode of the electronic component. In the lowermost insulation layer, via-conductor opening (51S) is formed to reach the second conductive layer, a through-hole conductor or an electrode of the electronic component (FIG. 4(D)).

(10) Electroless plating is performed, and electroless plated film 42 is formed on the inner walls of via-conductor openings and on the copper foils (FIG. 4(E)).

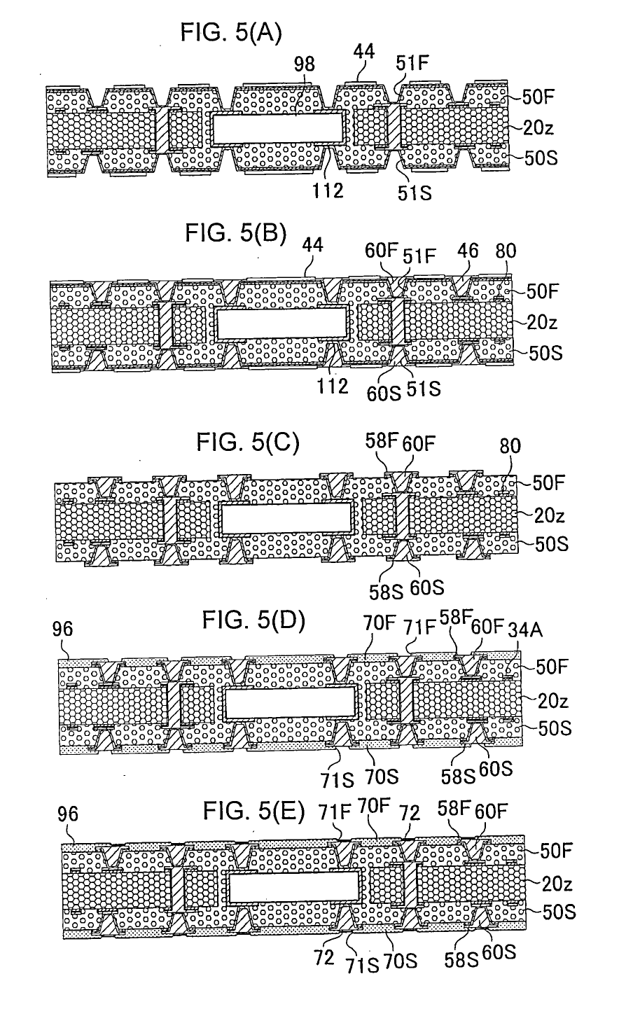

(11) Plating resist 44 is formed on electroless plated film 42 (FIG. 5(A)). The plating resist is formed on the electroless plated film in the frame section and on the electroless plated film in the unit section. The plating resist is formed in the frame section so that the dummy pattern shown in FIG. 7 is formed. FIG. 7(C) shows a plan view of the plating resist. The plating resist is indicated by lines in FIG. 7(C). The dummy pattern is formed in portions where no plating resist is present.

(12) Next, electrolytic plating is performed, and electrolytic plated film 46 is formed on portions of electroless plated film 42 exposed from plating resist 44 (FIG. 5(B)).

(13) Plating resist 44 is removed using a 5% NaOH solution. Then, electroless plated film 42 and copper foil 48 exposed from electrolytic copper plated film are removed by etching. The dummy pattern shown in FIG. 7(A) is formed in the frame section. One conductive portion is linked to other conductive portions by multiple connection lines. Conductive portions are linked to each other by intersecting connection lines in FIG. 7(A). Intersecting connection lines are shown in FIG. 7(D). Two connection lines (82T1, 82T2) intersect each other. Simultaneously, uppermost and lowermost conductive layers and uppermost and lowermost via conductors are formed (FIG. 5(C)). The uppermost and lowermost conductive layers include the dummy pattern formed in the frame section. The upper and lower buildup layers are completed.

(14) Solder-resist layers (70F, 70S) having openings (71F, 71S) are formed respectively on the upper and lower buildup layers (FIG. 5(D)). Openings 71 expose portions of conductive layers (58F, 58S) as well as via conductors (60F, 60S). Such portions work as pads.

(15) Metal film 72 made of a nickel layer and a gold layer on the nickel layer is formed on pads (FIG. 5(E)). Other than a nickel-gold layer, a nickel-palladium-gold layer may also be used as the metal film.

(16) Next, solder bump (76F) is formed on a pad in the upper buildup layer, and solder bump (76S) is formed on a pad in the lower buildup layer (FIG. 2(A)). Printed wiring board 100 is completed.

An IC chip is mounted on package substrate 10 through solder bump (76F) (not shown). During that time, since the printed wiring board has a dummy pattern in the frame section, warping of the printed wiring board is small in the unit section. The dummy pattern has intersecting connection lines. The intersecting connection lines restrict the movement of individual conductive portions. Thus, complex deformation of the printed wiring board is suppressed in the unit section. Accordingly, it is easier to mount electronic components such as IC chips. Mounting yield is enhanced. Connection reliability improves between electronic components and the printed wiring board. Next, multiple package substrates formed in the unit section are divided into individual package substrates. Package substrate 10 is mounted on a motherboard through solder bump (76S) (not shown).

### First Modified Example of First Embodiment

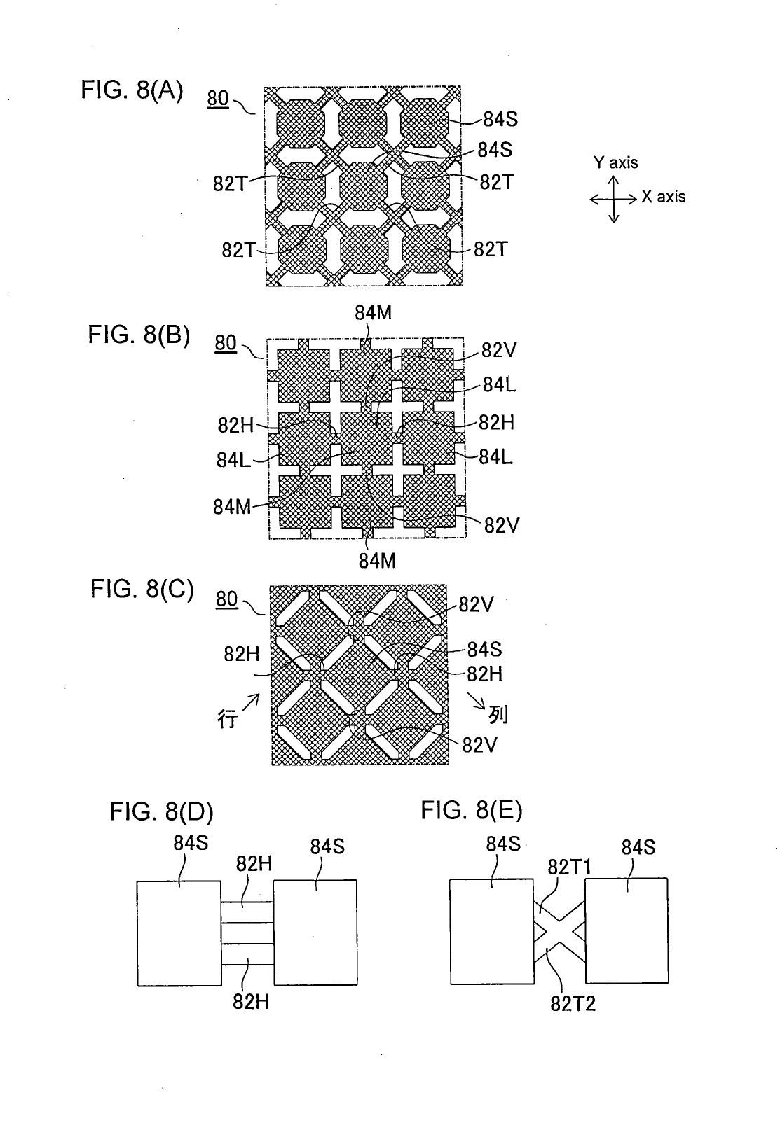

Axes (X, Y) are indicated in FIG. 8. Axis (X) in FIG. 8 is set to be the same as axis (X) in FIG. 1, and axis (Y) in FIG. 8 is set to be the same as axis (Y) in FIG. 1.

FIG. 8(A) is a schematic view of a dummy pattern according to a first modified example. A connection line extends from each apex of a conductive portion in FIG. 7(A). Stress tends to concentrate on an apex. Thus, when a connection line is linked to an apex of a conductive portion, line disconnection tends to occur between the conductive portion and the connection line. If line disconnection occurs, each conductive portion tends to move individually. Warping or undulation is likely to increase.

The same as in the first embodiment, the dummy pattern of the first modified example is made up of conductive portions arranged in a matrix and connection lines between conductive portions. The same as in the first embodiment, a conductive portion is linked to another conductive portion positioned diagonally above or diagonally below, or a conductive portion is linked to another conductive portion positioned diagonally above and diagonally below. One conductive portion is linked to multiple conductive portions by connection lines. As shown in FIG. 7(D), a conductive portion and other conductive portions are linked by multiple connection lines (two connection lines, for example). In the first modified example, a connection line extends from a side of a conductive portion. A connection line does not extend from an apex of a conductive portion. In addition, connection lines intersect each other, the same as in the first embodiment. Therefore, in the modified example, warping or deformation is small, the same as in the first embodiment. Since disconnection is unlikely to occur between a conductive portion and a connection line, deformation, undulation or warping is small even when thermal stress is exerted on the printed wiring board of the first modified example.

The shape of a conductive portion of the first modified example is an octagon, as shown in FIG. 8(A). Even if the shape of a conductive portion is other than an octagon, when a side of a conductive portion positioned diagonally above faces a side of a conductive portion positioned diagonally below, the side of one conductive portion is linked to the side of the other conductive portion by a connection line. In such a case, the same effects are achieved as those in the dummy pattern shown in FIG. 8(A).

In the first embodiment and the first modified example, conductive portions belong to rows or columns, and connection lines are not parallel to the rows or columns. Therefore, the movement of conductive portions is effectively suppressed by the connection lines. Warping, undulation or deformation is reduced. Rows are parallel to axis (X), and columns are parallel to axis (Y).

### Second Modified Example of First Embodiment

FIG. 8(B) is a schematic view of a dummy pattern according to a second modified example of the first embodiment. The dummy pattern of the second modified example is formed with conductive portions arranged in a matrix and having connection lines between conductive portions, the same as in the first embodiment. In the second modified example, except for conductive portions positioned at an end row or end column, a conductive portion is linked to other conductive portions positioned to the left, right, above and below. Conductive portion (84L) which belongs in a row is linked to another conductive portion by horizontal connection line (82H) parallel to the row. Conductive portion (84M) which belongs in a column is linked to another conductive portion by vertical connection line (82V) parallel to the column. A connection line extends from approximately the center of a side of a conductive portion.

In the second modified example, a connection line is linked to a side of a conductive portion. Disconnection is unlikely to occur between a conductive portion and a connection line. A connection line is formed parallel to a row or a column. Therefore, even when force in a direction diagonal to a row or a column is exerted on the printed wiring board, such force is unlikely to be transmitted through a connection line to an adjacent conductive portion. Accordingly, because of the frame section of the printed wiring board of the second modified example, deformation of the printed wiring board is reduced.

One conductive portion (84S) and another conductive portion (84S) may be linked by multiple connection lines (two connection lines, for example). Multiple connection lines (82H) may be formed parallel to each other (FIG. 8(D)). The same as in the first embodiment, it is preferred to connect conductive portions with intersecting connection lines (82T1, 82T2) (FIG. 8(E)). The rigidity of the dummy pattern increases.

### Third Modified Example of First Embodiment

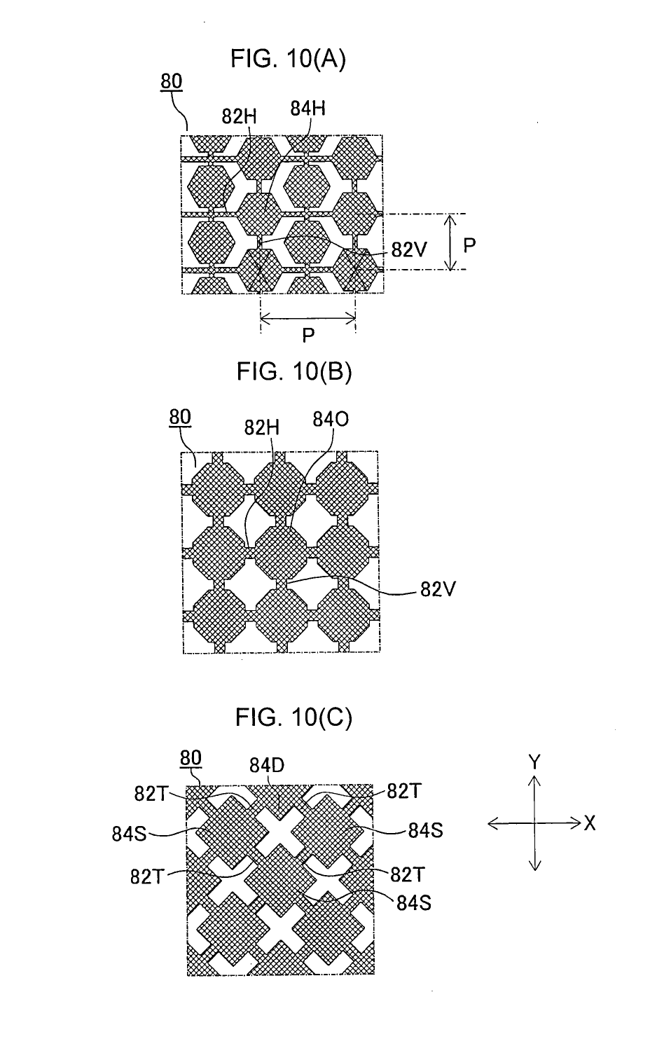

FIG. 10(B) is a schematic view of a dummy pattern according to a third modified example of the first embodiment. The shape of conductive portion (84O) of the third modified example is an octagon. Connection lines are formed parallel to a row or a column. Since an octagon has more corners than a rectangle does, stress on each corner is reduced, and warping of the printed wiring board is reduced.

### Fourth Modified Example of First Embodiment

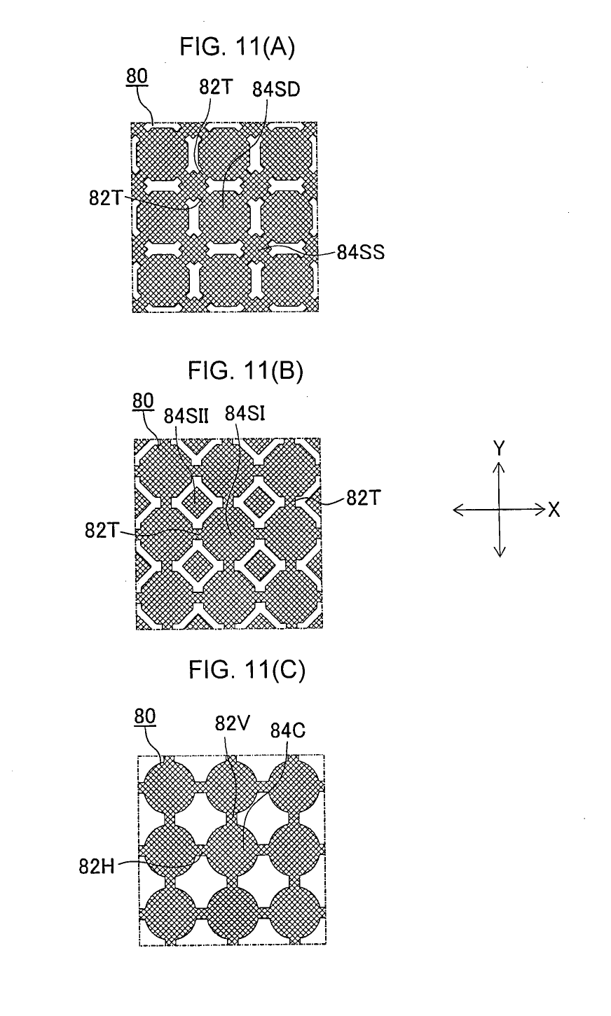

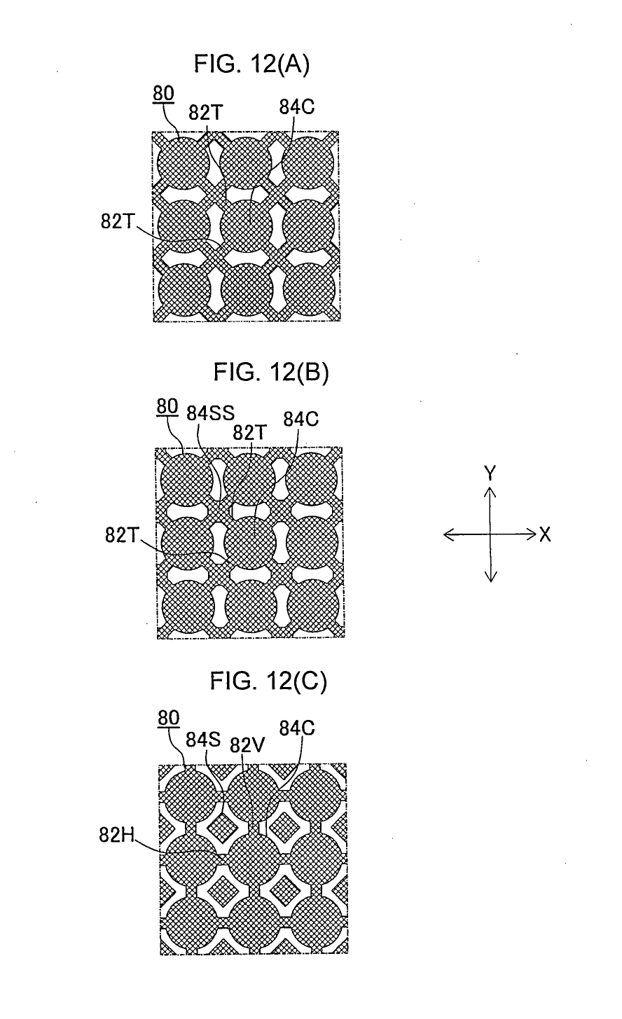

FIG. 11(C) and FIG. 12(A) are schematic views of a dummy pattern according to a fourth modified example. In the fourth modified example, the shape of a conductive portion is a circle. Since no angle is formed in a conductive portion, stress is not concentrated on a certain spot of a conductive portion. Thus, warping, deformation and undulation are reduced. FIG. 11(C) and FIG. 12(A) show the connection lines and the way conductive portions are linked by connection lines. The methods shown in other embodiments and other modified examples may each apply to connection lines and the way conductive portions are linked by connection lines in the fourth modified example. In FIG. 11(C), connection lines are set to be parallel to rows and columns. In FIG. 12(A), connection lines are set to be diagonal to rows. Connection lines intersect each other.

In the first embodiment and modified examples of the first embodiment, conductive portions are arranged in a matrix. In the first embodiment and modified examples of the first embodiment, conductive portions are formed to be parallel to the products in the unit section. Strength in a direction parallel as well as in a direction vertical to the products is reinforced by conductive portions. When connection lines are formed to be diagonal to the products, strength in a direction diagonal to the products is also reinforced. Warping along a side or along a diagonal line of the printed wiring board is reduced. When connection lines intersect each other, warping is further reduced. Since warping along a diagonal line is the most significant, when warping is reduced along a diagonal line, it becomes easier to mount an electronic component on the printed wiring board. In addition, reliability between electronic components and the printed wiring board is enhanced.

### Second Embodiment

FIG. 8(C) and FIG. 10(C) are schematic views of a dummy pattern according to a second embodiment. In the second embodiment, conductive portions are set to be diagonal to the outline of a printed wiring board. In the second embodiment, rows and columns of the matrix are diagonal to the outline of the printed wiring board. Columns are diagonal to axes (X, Y), and rows are diagonal to axes (X, Y). Connection lines linking conductive portions to each other may be set in the way shown in the first embodiment or the way shown in the second embodiment. In FIG. 10(C), a side of a conductive portion is linked to a side of another conductive portion. In FIG. 8(C), an apex of a conductive portion is linked to an apex of another conductive portion.

In the second embodiment, conductive portions are formed to be diagonal to the products in the unit section of the printed wiring board. Strength at diagonal positions of the printed wiring board is reinforced. Therefore, warping along a diagonal line of the printed wiring board is reduced. When connection lines are formed to be parallel to a side of the printed wiring board, strength in a direction parallel to the side of the printed wiring board is also reinforced. Such an example is shown in FIG. 8(C). Accordingly, warping along a long side or a short side of the printed wiring board is reduced, and warping of each product is also reduced.

### First Modified Example of Second Embodiment

FIG. 11(A) is a schematic view of a dummy pattern according to a first modified example of the second embodiment. The first modified example of the second embodiment has conductive portions with differing shapes. As shown in FIG. 11(A), some conductive portions are in a different shape from other conductive portions. There are square conductive portions (84SS) and octagonal conductive portions (84SD) in FIG. 11(A). A side of a conductive portion is linked to a side of another conductive portion by a connection line as shown in FIG. 11(A). Alternatively, a corner of a conductive portion may be linked to a side of another conductive portion by a connection line.

A side of square conductive portion (84SS) is linked to a side of octagonal conductive portion (84SD) by connection line (82T). Opposing sides are linked by a connection line (82T). In FIG. 11(A), conductive portions and connection lines are formed to be diagonal to a side of the printed wiring board. Warping along a diagonal line is reduced. Each product is arranged to be parallel to a side of the printed wiring board. Warping along the side of the printed wiring board is reduced. Warping is reduced in the printed wiring board.

Since conductive portions of differing shapes are formed in the first modified example of the second embodiment, it is easier to adjust the ratio of conductor volume to the volume of space in the frame section. The degree of warping or direction of warping can be controlled.

For other embodiments and other modified examples, it is also an option to have conductive portions with differing shapes, the same as in the first modified example of the second embodiment. In any of the embodiments and modified examples, a corner of a conductive portion may be linked to a side of another conductive portion by a connection line.

When conductive portions have differing shapes, the rigidity of the frame section can be adjusted by such a dummy pattern. By adjusting positions of conductive portions with differing shapes or differing sizes, warping or undulation of the printed wiring board is reduced. When both the shape and size are different, it is easier to adjust the strength of the frame section.

### Second Modified Example of Second Embodiment

FIG. 12(B) is a schematic view of a dummy pattern according to a second modified example of the second embodiment. The dummy pattern includes conductive portion (84C) with a circular shape set to be larger than the square shape and conductive portion (84SS) with a square shape set to be smaller than the circular shape. Conductive portion (84C) and conductive portion (84SS) are arranged alternately. Due to the circular shape of conductive portions, stress tends not to concentrate in one spot of a conductive portion. For example, if the shape of a larger conductive portion is an octagon, a side of the conductive portion may be linked to a corner of another conductive portion by a connection line.

### Third Embodiment

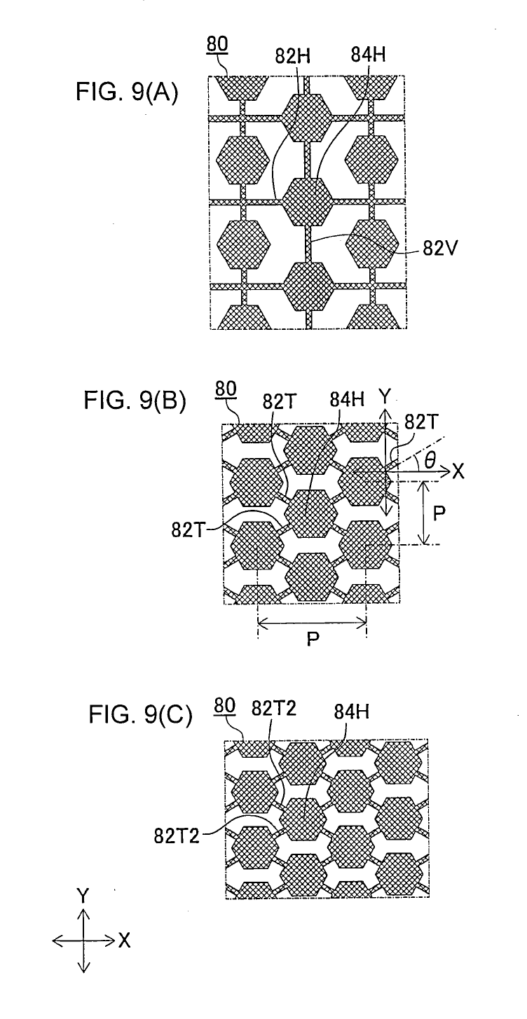

Axes (X, Y) are indicated in FIG. 9. Axis (X) shown in FIG. 9 is set to be the same as axis (X) in FIG. 1, and axis (Y) shown in FIG. 9 is set to be the same as axis (Y) in FIG. 1.

FIG. 9(A) is a schematic view of a dummy pattern according to a third embodiment. In the third embodiment, conductive portions that belong in a row are formed in alternating rows, and conductive portions that belong in a column are formed in alternating columns. The shape of a conductive portion in FIG. 9(A) is a hexagon. Because there are more corners in a hexagon than in a square, stress is dispersed. Conductive portions and connection lines are formed to be parallel to a side of a printed wiring board.

When a dummy pattern is formed in a frame section, the weight of the frame section increases. When the temperature of a printed wiring board rises, the strength of the resin in the printed wiring board decreases. Warping of the printed wiring board tends to be greater due to the weight of the frame section.

However, since conductive portions are formed in every alternating row or column in the third embodiment, the weight of the frame section is smaller. Thus, in the third embodiment, the warping of the printed wiring board is suppressed because of the frame section. Also, warping of the printed wiring board caused by the weight of the frame section is reduced. As a result, according to the third embodiment, warping of the printed wiring board at high temperatures is reduced.

### First Modified Example of Third Embodiment

FIG. 9(B) is a schematic view of a dummy pattern according to a first modified example of the third embodiment. In the third embodiment, a conductive portion is linked by connection lines to conductive portions positioned to the left, right, above and below. By contrast, in the first modified example, a conductive portion is linked by a connection line to a conductive portion positioned diagonally above or below. In the first modified example, four connection lines extend from one conductive portion. Four connection lines extend from different sides respectively. Four connection lines extend diagonally above to the right, below to the right, above to the left, and below to the left respectively. In FIG. 9(B), a connection line is set to be diagonal to a side of the printed wiring board. Angle (θ) made by a connection line and a row (axis X) is approximately 30 degrees.

### Second Modified Example of Third Embodiment

FIG. 9(C) is a schematic view of a dummy pattern according to a second modified example of the third embodiment. Pitch (P) of conductive portions in the first modified example is different from that in second modified example. Pitch (P) is the distance between central points of adjacent conductive portions, or the distance between gravity centers of adjacent conductive portions. Pitch (P) is the distance between conductive portions that belong in the same row or column. Since the pitch of the second modified example is smaller than that of the first modified example, the rigidity of the frame section of the second modified example is higher than that of the first modified example.

### Third Modified Example of Third Embodiment

FIG. 10(A) is a schematic view of a dummy pattern according to a third modified example of the third embodiment. In the third modified example, pitch (P) of conductive portions that belong in a row is different from pitch (P) of conductive portions that belong in a column. Setting a pitch in a row different from that in a column may apply to any embodiment and any modified example. By setting different pitches, it is easier to change the ratio of conductor volume to the volume of space in the frame section. The degree of warping or the direction of warping can be controlled. In addition, the ratio of conductor volume in the unit section to conductor volume in the frame section is easier to adjust. Warping of the printed wiring board is reduced.

### Fourth Embodiment

FIG. 11(B) is a schematic view of a dummy pattern according to a fourth embodiment.

The dummy pattern of the fourth embodiment is formed with first conductive portions (84SI) formed in a matrix, connection lines (82T) linking first conductive portions, and second conductive portions (84SII). Second conductive portions are independent. A second conductive portion is surrounded by first conductive portions. A second conductive portion is not linked to a first conductive portion or to a connection line. In FIG. 11(B), a second conductive portion (84SII) is surrounded by four first conductive portions (84SI). In the fourth embodiment, since first conductive portions are linked to connection lines, undulation or deformation is controlled by the first conductive portions and connection lines. Then, warping is controlled by independent second conductive portions. Thus, warping, undulation and deformation are reduced in the fourth embodiment. Also, directions of warping may be set to be the same. In the fourth embodiment, rigidity of the frame section is effectively enhanced.

In FIG. 11(B), octagonal conductive portion (84SI) set larger than a square conductive portion is a first conductive portion, and square conductive portion (84SII) set smaller than an octagonal conductive portion is a second conductive portion. Octagonal conductive portions (84SI) are linked by connection line (82T) parallel to a row and connection line (82T) parallel to a column. Square conductive portion (84SII) is independent, and is surrounded by four octagonal conductive portions (84SI). In FIG. 11(B), first conductive portions, connection lines and second conductive portions are formed parallel to a side of the printed wiring board. Connection lines are not formed to be diagonal to a side of the printed wiring board, but the strength of the printed wiring board in a diagonal direction is reinforced by second conductive portions.

### First Modified Example of Fourth Embodiment

FIG. 12(C) is a schematic view of a dummy pattern according to a first modified example. In the first modified example, the shape of a first conductive portion is a circle, and the shape of a second conductive portion is a square. The shape of a first conductive portion and the shape of a second conductive portion are preferred to be circular. The size of a first conductive portion is preferred to be greater than that of a second conductive portion.

Products are set to be parallel to a side of a printed wiring board in each embodiment and each modified example. Connection lines in each embodiment and each modified example are preferred to intersect as shown in FIG. 7(D).

When dummy wiring lines are independent of each other, and no conductor is formed between the dummy wiring lines, the rigidity of the printed wiring board between dummy wiring lines is thought to be low. Accordingly, it is thought to be difficult to reduce warping in such a printed wiring board.

A printed wiring board according to an embodiment of the present invention may exhibit only a small degree of warping.

A printed wiring board according to an embodiment of the present invention has a unit section containing multiple products and a frame section formed along the periphery of the unit section. Then, a dummy pattern is formed to have multiple conductive portions and connection lines formed in the space between conductive portions. A conductive portion is linked to multiple conductive portions by connection lines.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring board, comprising:
a unit section comprising a plurality of product portions; and
a frame section formed along the periphery of the unit section,
wherein the frame section has a dummy pattern comprising a plurality of conductive portions and a plurality of connection lines such that the plurality of connection lines is formed in spaces between the conductive portions and linking the conductive portions.

2. A wiring board according to claim 1, wherein the conductive portions have a same shape.

3. A wiring board according to claim 1, wherein each of the product portions has an electronic component built in, and the plurality of conductive portions is formed in a matrix.

4. A wiring board according to claim 2, wherein each of the conductive portions has a polygonal shape.

5. A wiring board according to claim 4, wherein each of the conductive portions has one of a rectangular shape, a hexagonal shape and an octagonal shape.

6. A wiring board according to claim 2, wherein each of the conductive portions has a circular shape.

7. A wiring board according to claim 4, wherein the plurality of connection lines is formed such that each of the connection lines is extending from corners of the conductive portions, respectively.

8. A wiring board according to claim 4, wherein the plurality of connection lines is formed such that each of the connection lines is extending from sides of the conductive portions, respectively.

9. A wiring board according to claim 1, wherein the plurality of conductive portions is formed in a matrix.

10. A wiring board according to claim 1, wherein the plurality of connection lines is formed such that the plurality of connection lines comprises two intersecting connection lines.

11. A wiring board according to claim 1, wherein the plurality of conductive portions includes a plurality of first conductive portions and a plurality of second conductive portions, the plurality of first conductive portions is formed in a matrix and linked through the connection lines, each of the second conductive portions is surrounded by the first conductive portions and is an independent portion, and each of the first conductive portions has a size which is greater than a size of each of the second conductive portions.

12. A wiring board according to claim 9, wherein the plurality of conductive portions is formed such that the conductive portions are extending parallel to the plurality of product portions, and the plurality of connection lines is formed such that the connection lines are extending in diagonal directions with respect to the plurality of product portions.

13. A wiring board according to claim 12, wherein the plurality of connection lines is formed such that the plurality of connection lines comprises two intersecting connection lines.

14. A wiring board according to claim 1, wherein the frame section has a plurality of opening portions, and the plurality of product portions is formed in the opening portions of the frame section, respectively.

15. A wiring board according to claim 3, wherein the conductive portions have a same shape.

16. A wiring board according to claim 3, wherein each of the conductive portions has a polygonal shape.

17. A wiring board according to claim 16, wherein each of the conductive portions has one of a rectangular shape, a hexagonal shape and an octagonal shape.

18. A wiring board according to claim 3, wherein each of the conductive portions has a circular shape.

19. A wiring board according to claim 3, wherein the plurality of connection lines is formed such that the plurality of connection lines comprises two intersecting connection lines.

20. A wiring board according to claim 3, wherein the frame section has a plurality of opening portions, and the plurality of product portions is formed in the opening portions of the frame section, respectively.
